(19) United States
(12) Patent Application Publication
(10) Pub. No.: US 2026/0293222 A1
(43) Pub. Date: Sep. 24, 2026

(54) QUANTUM SENSOR AND QUANTUM SENSING APPARATUS

(71) Applicant: Toyota Motor Engineering & Manufacturing North America, Inc., Plano, TX (US)

(72) Inventors: Ercan M. Dede, Ann Arbor, MI (US); Paul Donald Schmalenberg, Ann Arbor, MI (US); Shailesh N. Joshi, Ann Arbor, MI (US)

(73) Assignees: Toyota Motor Engineering & Manufacturing North America, Inc., Plano, TX (US); Toyota Jidosha Kabushiki Kaisha, Aichi-ken (JP)

(21) Appl. No.: 19/087,311

(22) Filed: Mar. 21, 2025

(51) Int. Cl. H10D 48/00; H10D 62/53; H10D 62/832; H10F 39/00; H10F 39/10; H10F 39/18

(52) U.S. Cl. CPC H10D 48/383; H10D 62/53; H10D 62/8325; H10F 39/107; H10F 39/182; H10F 39/8053

(57) ABSTRACT

A quantum sensor includes a 3D lattice structure including a silicon carbide core and voids, and a plurality of color centers located within a boundary of the 3D lattice structure, wherein each of the plurality of color centers includes a single-defect photon emitter. A method includes forming a porous mask in a substrate via interference lithography, the porous mask defining a 3D grid pattern, introducing silicon carbide into the porous mask, wherein the silicon carbide is in the form of silicon carbide powder or a silicon carbide slurry, sintering or curing the silicon carbide at a first temperature to form a green body ceramic part, and after removing the porous mask, sintering the green body ceramic part at a second temperature to form a 3D lattice structure, wherein the second temperature is higher than the first temperature, and wherein the 3D lattice structure comprises a silicon carbide core and voids.

### TECHNICAL FIELD

Embodiments generally relate to sensors. More particularly, embodiments relate to quantum sensors and an apparatus using a quantum sensor to measure an external stimulus.

### BACKGROUND

Color centers made of single-defect photon emitters (e.g., materials having quantum spin defects) emit light and are known to be highly sensitive to magnetic fields or certain other external phenomena, such as microwave/electromagnetic radiation. Quantum materials that include color centers can be used to create sensors.

### SUMMARY OF PARTICULAR EXAMPLES

In some embodiments, a quantum sensor includes a three-dimensional (3D) lattice structure including a silicon carbide core and a plurality of voids, and a plurality of color centers located within a boundary of the 3D lattice structure, wherein each of the plurality of color centers includes a single-defect photon emitter.

In some embodiments, a method includes forming a porous mask in a substrate via interference lithography, wherein the porous mask defines a three-dimensional grid pattern, introducing silicon carbide into the porous mask, wherein the silicon carbide is in the form of silicon carbide powder or a silicon carbide slurry, sintering or curing the silicon carbide at a first temperature to form a green body ceramic part, and after removal of the porous mask, sintering the green body ceramic part at a second temperature to form a three-dimensional (3D) lattice structure, wherein the second temperature is higher than the first temperature, and wherein the 3D lattice structure comprises a silicon carbide core and a plurality of voids.

In some embodiments, an apparatus includes a quantum sensor including a three-dimensional (3D) lattice structure comprising a silicon carbide core and a plurality of voids, and a plurality of color centers located within a boundary of the 3D lattice structure, wherein each of the plurality of color centers includes a single-defect photon emitter, a light source to emit light at a first frequency, wherein the light source is arranged adjacent to a first side of the quantum sensor and is to emit the light at the first frequency into the quantum sensor, an imaging sensor array arranged adjacent to a second side of the quantum sensor, and an electromagnetic field source adjacent to the quantum sensor, wherein the electromagnetic field source is to emit a modulated electromagnetic field into the quantum sensor.

In some embodiments, a method includes supplying power to a quantum sensing apparatus, exposing the quantum sensing apparatus to an external stimulus, measuring an output of the quantum sensing apparatus after the power is supplied to the quantum sensing apparatus, and determining from the output of the quantum sensing apparatus a strength and direction of the external stimulus, wherein the quantum sensing apparatus includes a quantum sensor including a three-dimensional (3D) lattice structure including a silicon carbide core and a plurality of voids, and a plurality of color centers located within a boundary of the 3D lattice structure, wherein each of the plurality of color centers includes a single-defect photon emitter, a light source to emit light at a first frequency, wherein the light source is arranged adjacent to a first side of the quantum sensor and is to emit the light at the first frequency into the quantum sensor, an imaging sensor array arranged adjacent to a second side of the quantum sensor, and an electromagnetic field source adjacent to the quantum sensor, wherein the electromagnetic field source is to emit a modulated electromagnetic field into the quantum sensor, wherein, when exposed to light at the first frequency and to the modulated electromagnetic field, each of the plurality of color centers emits light at a second frequency, and wherein, for respective ones of the plurality of color centers, an intensity of the light emitted at the second frequency varies based on exposure of the respective ones of the plurality of color centers to an external stimulus.

### BRIEF DESCRIPTION OF THE DRAWINGS

The various advantages of the embodiments will become apparent to one skilled in the art by reading the following specification and appended claims, and by referencing the following drawings, in which:

FIG. 1 provides a block diagram illustrating a scenario for measuring an external stimulus using a quantum sensor according to one or more embodiments;

FIG. 2 provides a diagram illustrating an example outline of a three-dimensional (3D) lattice structure according to one or more embodiments;

FIG. 3 provides a diagram illustrating an example 2D slice of a 3D lattice structure for a quantum sensor according to one or more embodiments;

FIGS. 4A-4B provide diagrams illustrating another example 2D slice of a 3D lattice structure for a quantum sensor according to one or more embodiments;

FIG. 5 provides a diagram illustrating an example 2D slice of a quantum sensor according to one or more embodiments;

FIG. 6 provides a diagram illustrating another example 2D slice of a quantum sensor according to one or more embodiments;

FIG. 7 provides a diagram illustrating an example method of producing a 3D lattice structure for a quantum sensor according to one or more embodiments;

FIGS. 8A-8B provide process flow diagrams illustrating an example method of producing a 3D lattice structure for a quantum sensor according to one or more embodiments;

FIG. 9 provides a diagram illustrating an example of a quantum sensing apparatus according to one or more embodiments; and

FIG. 10 provides a process flow diagram illustrating an example method of operating a quantum sensing apparatus according to one or more embodiments.

### DESCRIPTION OF EMBODIMENTS

Technology as described herein provides a quantum sensor and a production method thereof. The described technology further provides a quantum sensing apparatus, based on the quantum sensor, and a method of operating the quantum sensing apparatus for measuring an external stimulus, such as a magnetic field, an electric field, a thermal field, or a strain field imparted (e.g., applied) to the quantum sensor. As described more fully herein, the quantum sensor includes a three-dimensional (3D) lattice structure comprising a silicon carbide core and a plurality of voids; and a plurality of color centers located within a boundary of the 3D lattice structure, where each of the plurality of color centers includes a single-defect photon emitter. As described herein, functionalized silicon carbide powder (including color center particles) can be used to produce the 3D lattice structure for the quantum sensor.

The quantum sensing apparatus includes a quantum sensor, a light source to emit light at a first frequency, wherein the light source is arranged adjacent to a first side of the quantum sensor, and an imaging sensor array arranged adjacent to a second side of the quantum sensor. When exposed to (e.g., irradiated or illuminated with) light at the first frequency, and subject to an externally-applied microwave/electromagnetic (“MW/EM”) source field, each of the plurality of color centers in the quantum sensor is to emit light at a second frequency. For respective ones of the plurality of color centers, an intensity of the light to be emitted at the second frequency is to vary based on exposure of the respective ones of the plurality of color centers to an external stimulus (such as a magnetic field, an electric field, a thermal field, or a strain field imparted to the 3D lattice structure).

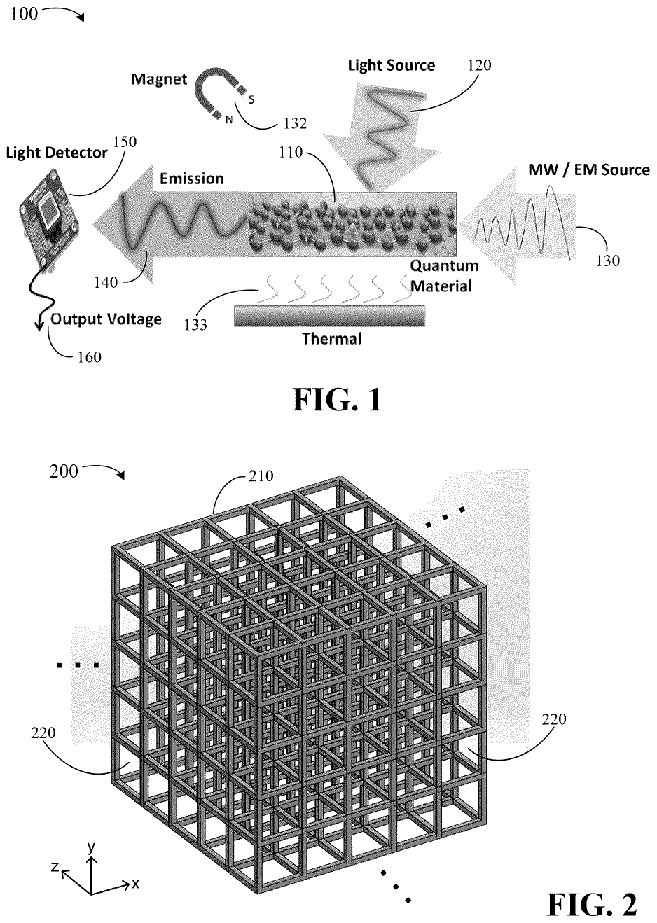

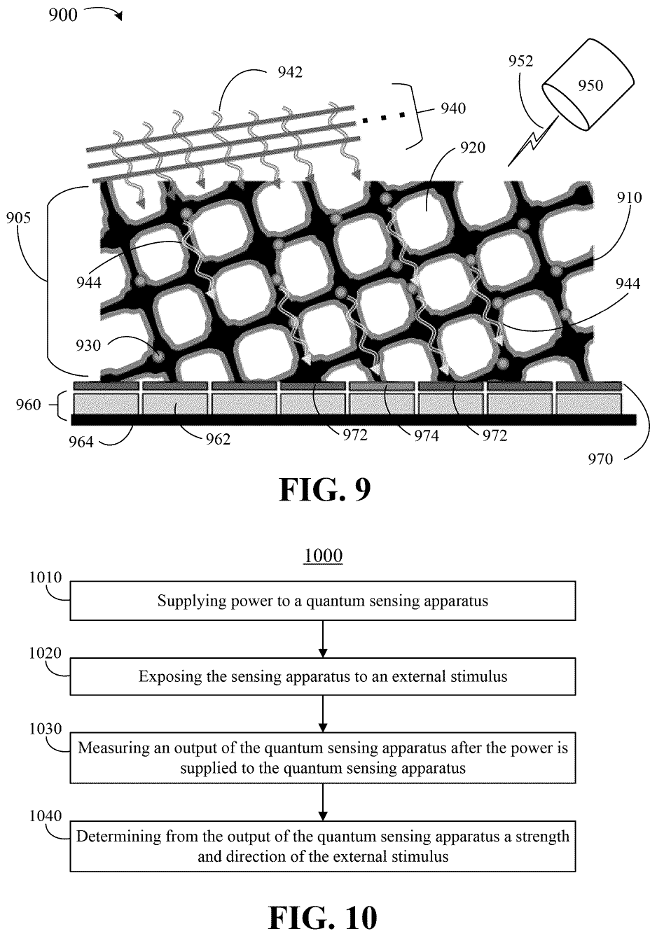

FIG. 1 provides a block diagram illustrating a scenario 100 for measuring an external stimulus using a quantum sensor according to one or more embodiments, with reference to components and features described herein including but not limited to the figures and associated description. Understanding the scenario 100 provides a basis for a quantum sensing apparatus (such as the quantum sensing apparatus described more fully below with reference to FIG. 9). As shown in FIG. 1, the scenario 100 includes quantum material 110, a light source 120, and an externally-applied microwave/electromagnetic (MW/EM) field from a MW/EM source 130, forming a quantum sensing apparatus to detect an external stimulus such as a magnetic field 132 or a thermal field 133. A detectable external stimulus can also include an electric field or a strain field (not shown in FIG. 1).

The quantum material 110 includes a plurality of color centers located, for example, within a boundary of three-dimensional (3D) structure (such as a lattice structure). In embodiments, the 3D structure includes silicon carbide. The boundary of the 3D structure is an imaginary 3D shape or “shell” that encompasses the outermost portions of the 3D structure (e.g., the boundary lies at the outer edges of each side of the 3D structure), such that the entirety of the 3D structure lies within the boundary. Each of the plurality of color centers comprises a single-defect photon emitter. For example, defects within the structure of the quantum material (e.g., diamond, silicon carbide, hexagonal boron nitride, or similar material) are filled with another element, such as nitrogen, to create a color center. When exposed to a light source such as light at a first frequency (e.g., a first color such as green light) and subject to an applied and modulated MW/EM field from the MW/EM source 130, each of the plurality of color centers (i.e., each color center so exposed to the light from the light source) emits light at a second frequency (e.g., a second color such as red light). As one example, a color center made of functionalized silicon carbide (e.g., silicon carbide material having a single-defect photon emitter) emits red or infrared light. As another example, a color center made of nitrogen vacancy (NV) defective diamond material emits red light.

Color centers are sensitive to certain external stimuli such as, e.g., a magnetic field, an electric field, a thermal field or a strain field, when exposed to light and a modulated microwave/electromagnetic field. For a respective color center, an intensity of the light emitted at the second frequency will vary based on exposure of the respective color center to the external stimulus and in combination with the modulation of the applied MW/EM signal. By detecting the intensity of the light emitted by the color centers, the strength of the stimulus can be determined, e.g., via an Optically Detected Magnetic Resonance (ODMR) technique, which is well-known in the field of quantum sensing.

The light source 120 provides light having a first frequency. In response to the light source 120, the MW/EM source 130, and the external stimulus presented, the quantum material 110 emits light 140 at a second frequency. A light detector 150 (e.g., a light sensor such as a CMOS sensor) detects the light 140 emitted by the quantum material 110 (e.g., the light detector 150 measures an intensity of the light 140) and produces an output voltage 160 accordingly. By measuring the output voltage 160, at least a strength of the external stimulus can be determined. If the quantum material 110 includes a distribution of color centers and the light detector 150 includes an array of light sensors, spatial variation (e.g., such as directionality) of the external stimulus can also be determined based on a readout of the light sensor array output.

The externally-applied MW/EM source field causes resonance of the spin-defect in the quantum material 110 (color centers). The resonant frequency of the spin defect is primarily based on the fermi energy level of the defect atoms, such that it can vary based on the particular quantum material used. The base resonant frequency for the quantum material 110 can change based on the external stimulus, such as a thermal, strain, electric or magnetic field, that is imparted on the quantum material. When the external MW/EM source 130 is applied at the resonant frequency, the amplitude of the light emission from the quantum material 110 is reduced compared to the amplitude of light emitted by the quantum material 110 for other frequencies used in the applied MW/EM source 130. Thus, modulating or sweeping the frequencies of the MW/EM source 130 is used to find what frequency the resonance(s) is/are currently residing given the current external stimulus that is present. The current frequency of the resonance is compared against the base (e.g., ‘unmodified’) resonant frequency (e.g., the resonant frequency for the quantum material without the external stimulus), which is then used to estimate the external stimuli. The base resonant frequency is known or determined beforehand.

Typical ranges of resonant frequencies for various types of quantum material 110 will lie in the microwave and/or upper radio wave frequencies. As one example, when the quantum material 110 includes NV diamond defects, the frequencies of interest (potential resonant frequencies) range approximately from 2 GHz to 3.5 GHz. As another example, when the quantum material 110 includes silicon carbide (which can have many defect types), the frequencies of interest (potential resonant frequencies) can range, e.g., approximately from 0.5 GHz to 1.5 GHz, or 4 GHz to 6 GHz, etc., depending on the type of defect.

The potential types of stimuli to be measured by the quantum sensing apparatus described herein include a magnetic field (e.g., the magnetic field 132), a thermal field (e.g., the thermal field 133), an electric field or a strain field. The type of magnetic field or electric field as a stimulus to be measured is of a different frequency range than is used for the MW/EM source 130. For example, a magnetic field or electric field as a stimulus to be measured is typically either DC (i.e., frequency is 0 Hz) or relatively low frequency (e.g., less than 10 kHz).

FIG. 2 provides a simple diagram illustrating an example outline of a 3D lattice structure 200 according to one or more embodiments, with reference to components and features described herein including but not limited to the figures and associated description. As shown in FIG. 2, the outlined 3D lattice structure 200 includes a core 210 (e.g., a grid-like structure) and interstitial voids 220 (e.g., holes or spaces in between intersecting portions of the grid-like structure). The 3D lattice structure 200 can extend in any one or more of the three dimensions (e.g., along an X-axis, along a Y-axis, and/or along a Z-axis). In some embodiments, the 3D lattice structure 200 extends substantially along one or two dimensions but has a limited extension in a third dimension. The size/extent of the 3D lattice structure 200 in various dimensions can be determined or designed based on a particular sensing application. It will be understood that the outlined 3D lattice structure 200 shown in FIG. 2 is but one non-limiting example, and other examples of 3D lattice structures are contemplated within the scope of this disclosure.

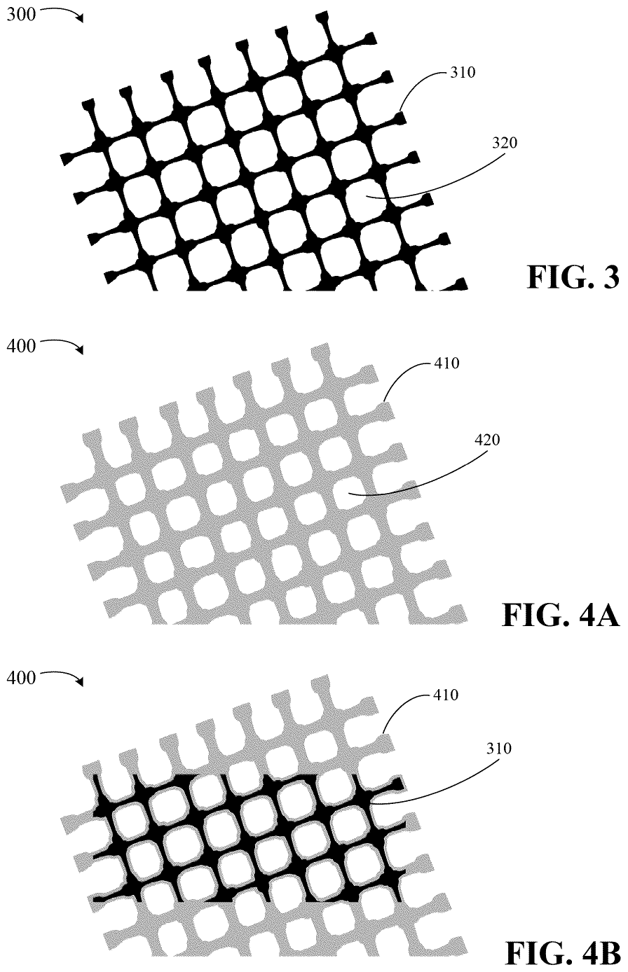

FIG. 3 provides a diagram illustrating an example two-dimensional (2D) slice (e.g., a cross-sectional slice) of a portion of a 3D lattice structure 300 for a quantum sensor according to one or more embodiments, with reference to components and features described herein including but not limited to the figures and associated description. As shown in FIG. 3, the 3D lattice structure 300 includes a core 310 having a core material and a plurality of voids 320 (e.g., holes or spaces in between intersecting portions of the core). In embodiments, the core material for the core 310 is (or includes) silicon carbide (SiC). In embodiments, the 3D lattice structure 300 follows a shape and geometry the same as or similar to the outlined lattice structure 200 (FIG. 2, already discussed), such that the core of the 3D lattice structure 310 follows (e.g., conforms to) the core 210 of the outlined lattice structure 200.

In embodiments the 3D lattice structure 300 further includes quantum material (such as, e.g., quantum material 110) in the form of a plurality of color centers (not shown in FIG. 3) that are located within a boundary of the 3D lattice structure 300. The boundary of the 3D lattice structure 300 is an imaginary 3D shape or “shell” that encompasses the outermost portions of the 3D lattice structure 300 (e.g., the boundary lies at the outer edges of each side of the 3D lattice structure 300), such that the entirety of the 3D lattice structure 300 lies within the boundary. Thus, in embodiments the color centers are located in or on the core 310 and/or in one or more of the voids 320 (i.e., which are within the boundary of the 3D lattice structure 300).

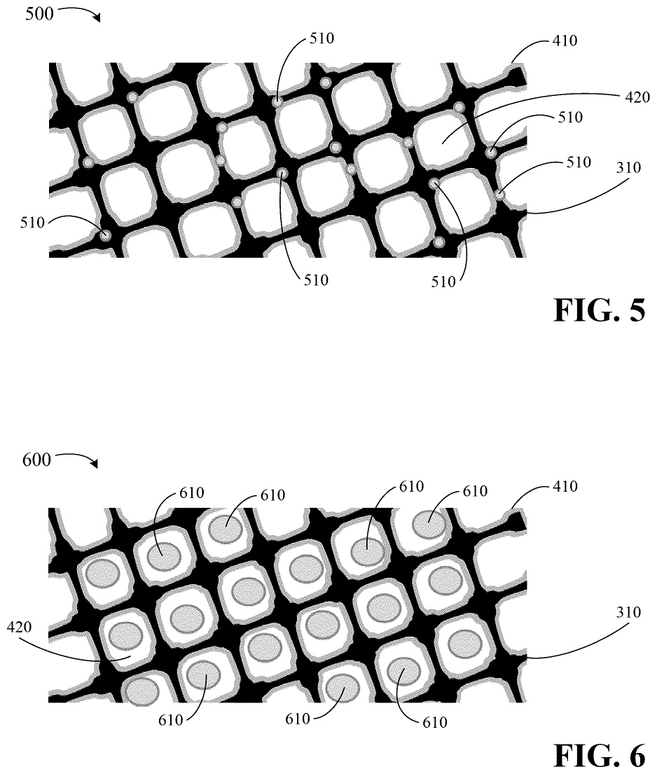

Each of the plurality of color centers includes a single-defect photon emitter including material such as, e.g., functionalized silicon carbide (e.g., silicon carbide material having a single-defect photon emitter) or nitrogen vacancy (NV) defective diamond material. As described more fully herein with reference to FIGS. 5-6, the plurality of color centers are, in some embodiments, located in or on the core 310 (e.g., a silicon carbide core) of the 3D lattice structure 300 and/or in one or more of the voids 320 of the 3D lattice structure 300.

FIGS. 4A-4B provide diagrams illustrating another example 2D slice (e.g., a cross-sectional slice) of a portion of a 3D lattice structure 400 for a quantum sensor according to one or more embodiments, with reference to components and features described herein including but not limited to the figures and associated description. The 3D lattice structure 400 includes an optional cladding layer 410 disposed over at least a portion of a core (e.g., a silicon carbide core) of the 3D lattice structure 400. The core of the 3D lattice structure 400 corresponds to the core 310 (FIG. 3, already discussed). The 3D lattice structure 400 further includes a plurality of voids 420 (e.g., holes or spaces in between intersecting portions of the cladded core). The plurality of voids 420 corresponds to the plurality of voids 320 (FIG. 3).

As shown in FIG. 4A, the cladding layer 410 covers the entirety of the core. For illustrative purposes, in FIG. 4B, the cladding layer 410 is shown such that the core 310 appears partially visible (e.g., as if a portion of the cladding layer 410 has been removed). The cladding layer 410 typically includes a material having a refractive index that is different than a refractive index of the core material. For example, in embodiments the refractive index of the cladding layer 410 is lower than the refractive index of the core 310, which provides for improved confinement of light within the core 310 (e.g., the cladding layer 410 helps to guide the light through the core 310 of the 3D lattice structure 400) while reducing or eliminating interaction between light in the core 310 and surrounding air. In some embodiments, the cladding layer 410 includes aluminum oxide (AL₂O₃), which has a lower refractive index (n~=1.75) than a core material silicon carbide (n~=2.65) typically used for the core 310. In some other embodiments, the cladding layer 410 includes silicon dioxide (SiO₂), which also has a lower refractive index than silicon carbide. In some embodiments, the cladding layer 410 covers a portion of but less than the entirety of the core.

The 3D lattice structure 400 further includes quantum material (such as, e.g., quantum material 110) in the form of a plurality of color centers (not shown in FIGS. 4A-4B) that are located within a boundary of the 3D lattice structure 400. Similar to the boundary for the 3D lattice structure 300 (as described herein with reference to FIG. 3), the boundary for the 3D lattice structure 400 is an imaginary 3D shape or “shell” that encompasses the outermost portions of the 3D lattice structure 400 (e.g., the boundary lies at the outer edges of each side of the 3D lattice structure 400), such that the entirety of the 3D lattice structure 400 lies within the boundary. Each of the plurality of color centers includes a single-defect photon emitter including material such as, e.g., functionalized silicon carbide (e.g., silicon carbide material having a single-defect photon emitter) or nitrogen vacancy (NV) defective diamond material. As described more fully herein with reference to FIGS. 5-6, the plurality of color centers are, in embodiments, located in or on the core 310 (e.g., a silicon carbide core) of the 3D lattice structure 400 and/or in one or more of the voids 420 of the 3D lattice structure 400.

FIG. 5 provides a diagram illustrating an example 2D slice (e.g., a cross-sectional slice) of a portion of a quantum sensor 500 according to one or more embodiments, with reference to components and features described herein including but not limited to the figures and associated description. The quantum sensor 500 includes a 3D lattice structure (e.g., corresponding to the 3D lattice structure 400) which includes the core 310 having the optional cladding layer 410, along with the plurality of voids 420. For illustrative purposes, in FIG. 5, the cladding layer 410 is shown such that the core 310 appears partially visible (e.g., as if a portion of the cladding layer 410 has been removed). In some embodiments, the 3D lattice structure of the quantum sensor 500 does not include the optional cladding layer 410 over the core 310 (e.g., the 3D lattice structure corresponds to the 3D lattice structure 300).

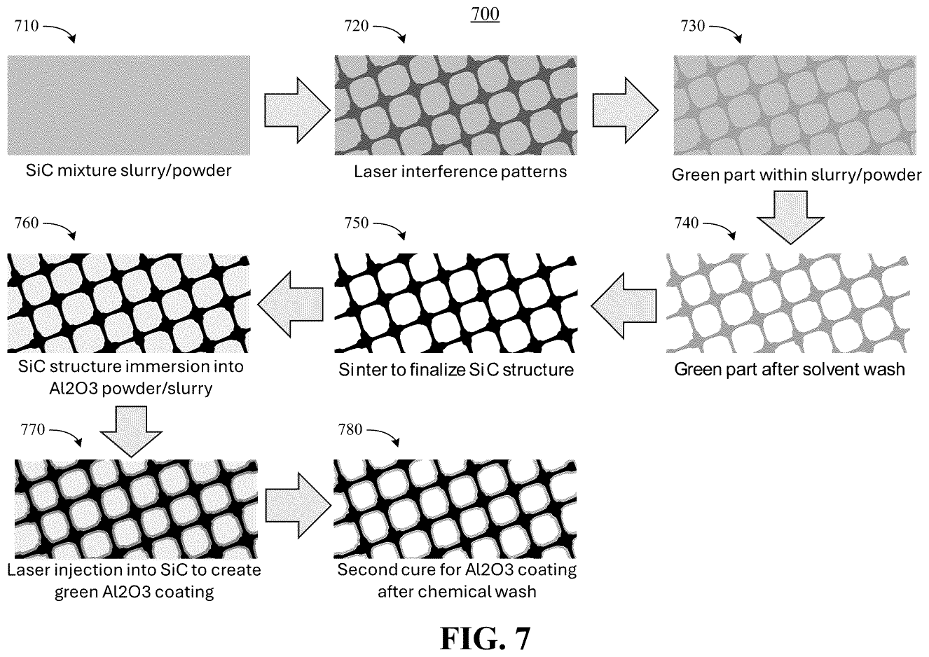

The quantum sensor 500 further includes a plurality of color centers 510 located within a boundary of the 3D lattice structure. As shown in FIG. 5, the plurality of color centers 510 are located in or on the core 310 of the 3D lattice structure (the color centers 510, which are typically on the order of a nanoscale, are shown enlarged for diagram clarity). In embodiments, one or more of the plurality of color centers 510 each includes functionalized silicon carbide (e.g., silicon carbide material having a single-defect photon emitter). In some embodiments, the color centers 510 are included with (or added to) silicon carbide material before or during production of the 3D lattice structure (e.g., as described herein with reference to FIG. 7). In some embodiments, the color centers 510 are formed during or after production of the 3D lattice structure via laser writing.

FIG. 6 provides a diagram illustrating another example 2D slice (e.g., a cross-sectional slice) of a portion of a quantum sensor 600 according to one or more embodiments, with reference to components and features described herein including but not limited to the figures and associated description. The quantum sensor 600 includes a 3D lattice structure (e.g., corresponding to the 3D lattice structure 400) which includes the core 310 having the optional cladding layer 410, along with the plurality of voids 420. For illustrative purposes, in FIG. 6, the cladding layer 410 is shown such that the core 310 appears partially visible (e.g., as if a portion of the cladding layer 410 has been removed). In some embodiments, the 3D lattice structure of the quantum sensor 600 does not include the optional cladding layer 410 over the core 310 (e.g., the 3D lattice structure corresponds to the 3D lattice structure 300).

The quantum sensor 600 further includes a plurality of color centers 610 located within a boundary of the 3D lattice structure. As shown in FIG. 6, the plurality of color centers 610 are located in one or more of the voids 420 of the 3D lattice structure. Color center materials for the color centers 610 can include, e.g., silicon carbide, diamond, hexagonal boron nitride or similar material. In some embodiments, one or more of the plurality of color centers 610 each includes a nanodiamond having nitrogen vacancy (NV) defective diamond material. In some embodiments one or more of the plurality of color centers 610 each includes a high-density group or ensemble of color center material (e.g., a group of functionalized silicon carbide particles). The group or ensemble of color center material typically is of a size similar to the size of a void 420. In some embodiments, the plurality of color centers 610 are drop cast into the plurality of voids 420 after production of the 3D lattice structure (e.g., as described herein with reference to FIG. 7).

In some embodiments, the 3D lattice structure for the quantum sensor 600 further includes a plurality of color centers located in or on the core 310 of the 3D lattice structure for the quantum sensor 600. Thus, for example, in some embodiments the quantum sensor 600 includes not only a plurality of color centers 610 in voids 420, but also a plurality of color centers 510 in or on the core 310.

FIG. 7 provides a diagram illustrating an example method 700 of producing a 3D lattice structure for a quantum sensor according to one or more embodiments, with reference to components and features described herein including but not limited to the figures and associated description. In embodiments, a 3D lattice structure produced according to the method 700 corresponds to one or more of the 3D lattice structure 300 (FIG. 3), the 3D lattice structure 400 (FIGS. 4A-4B), the 3D lattice structure for the quantum sensor 500 (FIG. 5) and/or the 3D lattice structure for the quantum sensor 600 (FIG. 6). In the method 700 as described herein, silicon carbide material is used for producing the core of the 3D lattice structure.

As shown in FIG. 7, illustrated process block 710 provides for using a quantum material (e.g., a thermal tolerable silicon carbide in powder form) to form a silicon carbide mixture. The silicon carbide mixture is formed as a slurry or powder. In embodiments, the silicon carbide mixture includes functionalized silicon carbide particles (e.g., the functionalized silicon carbide particles have one or more single-defect photon emitters). For example, in some embodiments the silicon carbide particles contain one or more defects that act as color centers; the defects can, e.g., be fabricated within a silicon carbide bulk substrate that is then ground to create the silicon carbide powder. In other embodiments, the particles having defects are grown. In some embodiments, the silicon carbide mixture does not include color centers; instead the color centers are added to the 3D lattice structure at a later stage. The silicon carbide mixture (e.g., formed as a powder or slurry), with or without functionalized silicon carbide particles (e.g., particles acting as color centers), is capable of being sintered at temperatures below 1000 degrees Celsius, as a non-limiting example.

In embodiments, to form the silicon carbide mixture as a slurry (i.e., a silicon carbide slurry), the silicon carbide (in powder form) is combined (e.g., mixed) with a liquid (e.g., water and/or other materials) which can also be in the form of a slurry. As one example, in some embodiments the silicon carbide (in powder form) is mixed with a slurry that includes liquid sodium, water glass and zirconia (e.g., zirconium powder). In some embodiments this slurry includes an optional forming polymer or binder (e.g., a polymeric binder).

Illustrated process block 720 provides for forming a porous mask from a bulk photoresist material using interference lithography. Coherent laser beams are directed through the bulk photoresist material; the laser beams intersect and therefore interfere with one another (i.e., a laser interference pattern) within the bulk photoresist material to form a pattern or template. For example, in some embodiments the laser beams form a grid pattern within the bulk photoresist material. The bulk photoresist is then developed by placing it in a development solution. Only the regions of the bulk photoresist material that were exposed to intersecting laser beams remain, thereby resulting in a porous mask.

It will be understood that forming the porous mask (part of block 720) and forming the silicon carbide mixture (e.g., as a slurry or a powder, as described herein with reference to block 710) can occur in any order. Once the porous mask and the silicon carbide mixture are both formed, illustrated process block 720 further provides for introducing the silicon carbide mixture into the voids (e.g., spaces) of the porous mask. For example, in some embodiments, the silicon carbide mixture is introduced into the voids of the porous mask through sonication; in other embodiments, the silicon carbide mixture is introduced into the voids of the porous mask through infiltration. Other techniques for introducing the silicon carbide mixture into the voids of the porous mask can be employed.

Illustrated process block 730 provides for sintering or curing the silicon carbide mixture (combined in block 720) at a relatively low first temperature to form a green body ceramic part. As a non-limiting example, in some embodiments the first temperature is less than 200 degrees Celsius, or similar temperature. For example, in some embodiments where the slurry includes an optional forming polymer or binder, the first temperature application cures the polymer/binder.

Illustrated process block 740 provides for removing the porous mask after forming the green body ceramic part. In embodiments, the porous mask is removed via a solvent (e.g., a solvent wash). For example, in some non-limiting embodiments acetone is used for a solvent wash to remove the porous mask. Other solvents can be employed as a solvent wash to remove the porous mask.

After removal of the porous mask, illustrated process block 750 provides for sintering the green body ceramic part at a second temperature to form a more fully dense silicon carbide composite ceramic lattice—i.e., a three-dimensional (3D) lattice structure having a silicon carbide core and voids. The second temperature, in a range, e.g., of 600-1800 degrees Celsius, is typically higher than the first temperature.

In embodiments where the silicon carbide mixture includes functionalized silicon carbide particles (e.g., particles having a single-defect photon emitters) as described herein for block 710, the 3D lattice structure includes a plurality of color centers located in or on the silicon carbide core of the 3D lattice structure. One consideration for selection of the color center material is the ability of the color center particles to withstand the heat applied for sintering without degrading. In some embodiments, color centers are added into the voids of the 3D lattice structure (e.g., as illustrated in FIG. 6) via the techniques discussed herein.

In embodiments where the silicon carbide mixture does not include functionalized silicon carbide particles (e.g., where the silicon carbide mixture contains conventional silicon carbide powder without color centers), the 3D lattice structure does not yet have a plurality of color centers located within a boundary of the 3D lattice structure. Color centers can be added to the 3D lattice structure by laser writing defects at specific locations on or within the core of the 3D lattice structure and/or by drop casting color centers into the voids of the sintered 3D lattice structure. In some embodiments, even if the silicon carbide mixture includes functionalized silicon carbide particles, additional color centers can be added to the 3D lattice structure by laser writing defects at specific locations on or within the core of the 3D lattice structure and/or by placing color centers into the voids of the sintered 3D lattice structure (e.g., via drop casting as described herein). In embodiments where an optional cladding layer is disposed over at least a portion of the silicon carbide core (as described herein), placement of color centers into the voids is deferred until the final cladding layer over the silicon carbide core is completed.

In some embodiments, the 3D lattice structure includes an optional cladding layer (such as, e.g., the cladding layer 410 in FIGS. 4A-4B, already discussed) disposed over at least a portion of the silicon carbide core. In some embodiments, the optional cladding layer includes aluminum oxide (AL₂O₃). Illustrated process block 760 provides for immersing the 3D lattice structure (from block 750) into a second mixture including aluminum oxide to form an uncured layer over at least a portion of the silicon carbide core. The second mixture can be aluminum oxide powder or a slurry that includes aluminum oxide (e.g., powder mixed into a liquid). Illustrated process block 770 provides for partially curing the uncured layer via laser exposure (e.g., as a catalyst) to form a partially cured layer. In some embodiments, the laser exposure is accomplished via laser injection into the 3D lattice structure with uncured layer. The result is a green coating (e.g., green aluminum oxide coating). Illustrated process block 780 provides for removing any remaining uncured portion of the uncured layer and, after removing the remaining uncured portion, sintering the partially cured layer to form the final cladding layer for the 3D lattice structure. In some embodiments, the remaining uncured portion is removed via a chemical wash. The sintering temperature for this portion of the process (block 780) is a higher temperature, e.g., in a range of 1200-1600 degrees Celsius. In some embodiments the optional cladding layer includes silicon dioxide (e.g., instead of aluminum oxide).

In some embodiments, the plurality of color centers are drop cast into the plurality of voids after production of the 3D lattice structure (e.g., including embodiments with the optional cladding layer). For example, the plurality of color centers (e.g., the color centers 610 in FIG. 6) are placed in a liquid suspension and the 3D lattice structure is immersed in the liquid suspension, such that the liquid suspension fills all or at least a portion of the voids (e.g., the voids 420 in FIG. 6). In some embodiments, the liquid includes a binder; in some other embodiments, the liquid does not include a binder. Then, the liquid is allowed to evaporate, leaving the color centers in the voids of the 3D lattice structure (e.g., in all or substantially all of the voids reached by the liquid suspension). Using a drop cast process to place color centers in the voids of the 3D lattice structure enables selection of color center materials without needing to consider their sintering properties in tandem.

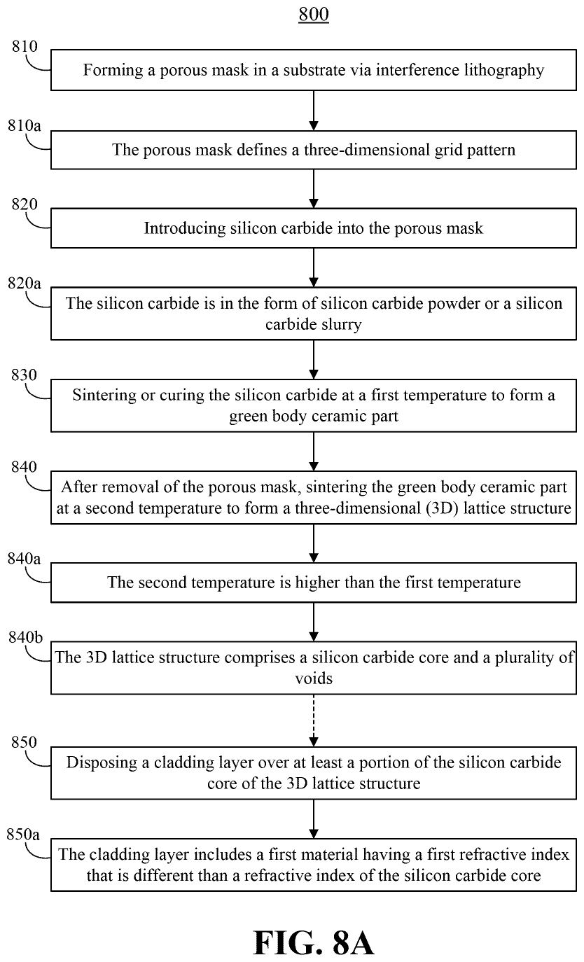

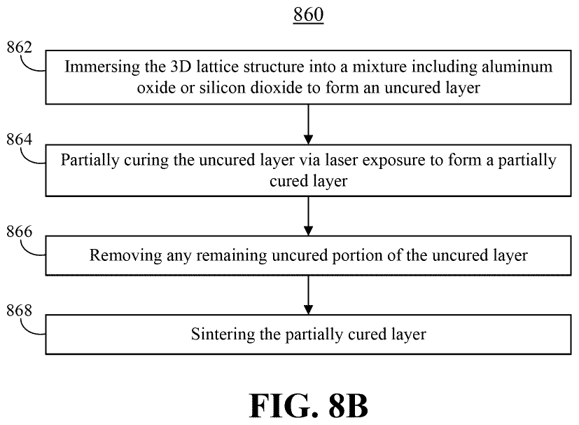

FIG. 8A provides a process flow diagram illustrating an example method 800 of producing a 3D lattice structure for a quantum sensor according to one or more embodiments, with reference to components and features described herein including but not limited to the figures and associated description. As shown in FIG. 8A, illustrated process block 810 provides for forming a porous mask in a substrate via interference lithography, where at block 810a the porous mask defines a three-dimensional grid pattern. Illustrated process block 820 provides for introducing silicon carbide into the porous mask, where at block 820a the silicon carbide is in the form of silicon carbide powder or a silicon carbide slurry. Illustrated process block 830 provides for sintering or curing the silicon carbide at a first temperature to form a green body ceramic part. Illustrated process block 840 provides for after removal of the porous mask, sintering the green body ceramic part at a second temperature to form a three-dimensional (3D) lattice structure, where at block 840a the second temperature is higher than the first temperature, and at block 840b the 3D lattice structure comprises a silicon carbide core and a plurality of voids.

In some embodiments, the silicon carbide includes a plurality of color centers, where each of the plurality of color centers comprises a single-defect photon emitter, and when the 3D lattice structure is formed the plurality of color centers are located within a boundary of the 3D lattice structure. In some embodiments, the silicon carbide slurry includes liquid sodium water glass, and in some embodiments the silicon carbide slurry further includes zirconium dioxide particles. In some embodiments, the method 800 further includes introducing a plurality of color centers into one or more of the voids of the 3D lattice structure. In some embodiments, the method 800 further includes laser writing a plurality of color centers in or on the silicon carbide core of the 3D lattice structure.

In some embodiments, the method 800 further includes, at illustrated process block 850, disposing a cladding layer over at least a portion of the silicon carbide core of the 3D lattice structure, where at block 850a the cladding layer comprises a first material having a first refractive index that is different than a refractive index of the silicon carbide core. Turning now to FIG. 8B, provided is a process flow diagram illustrating an example method 860 of disposing the cladding layer over at least the portion of the silicon carbide core of the 3D lattice structure according to one or more embodiments, with reference to components and features described herein including but not limited to the figures and associated description. The method 860 can be substituted for all or a portion of illustrated process block 850 (FIG. 8A, already discussed). Illustrated process block 862 provides for immersing the 3D lattice structure into a mixture including aluminum oxide or silicon dioxide to form an uncured layer. Illustrated process block 864 provides for partially curing the uncured layer via laser exposure to form a partially cured layer. Illustrated process block 866 provides for removing any remaining uncured portion of the uncured layer. Illustrated process block 868 provides for sintering the partially cured layer.

FIG. 9 provides a diagram illustrating an example 2D slice (e.g., a cross-sectional slice) of a portion of a quantum sensing apparatus 900 according to one or more embodiments, with reference to components and features described herein including but not limited to the figures and associated description. As shown in FIG. 9, the quantum sensing apparatus 900 includes a quantum sensor 905 (shown as a 2D slice), a light source 940, a MW/EM source 950, and an imaging sensor array 960. The quantum sensor 905 includes a 3D lattice structure, the 3D lattice structure including a silicon carbide core 910 along with a plurality of voids 920, and a plurality of color centers 930 located within a boundary of the 3D lattice structure. In embodiments the quantum sensor 905 corresponds to the quantum sensor 500 (FIG. 5, already discussed) or the quantum sensor 600 (FIG. 6, already discussed). In embodiments, the silicon carbide core 910 corresponds to the core 310 (FIG. 3, already discussed). In some embodiments, an optional cladding layer (e.g., as illustrated in FIG. 9), such as the cladding layer 410 (FIGS. 4A-4B, already discussed), is disposed over all or at least a portion of the silicon carbide core 910.

Each of the plurality of color centers 930 includes a single-defect photon emitter. In some embodiments, at least a portion of the plurality of color centers 930 are located in or on the silicon carbide core 910 of the 3D lattice structure. When exposed to light at the first frequency (e.g., light from the light source 940), and subject to an applied and modulated MW/EM field 952 (e.g., from the MW/EM source 950), each of the plurality of color centers 930 is to emit light at a second frequency. Under exposure to the light from the light source 940 and the modulated MW/EM field 952 from the MW/EM source 950, the color centers 930 are sensitive to certain external stimuli such as, e.g., a magnetic field, an electric field, a thermal field or a strain field. For a respective color center 930, an intensity of the light emitted at the second frequency will vary based on exposure of the respective color center 930 to the external stimulus. In embodiments, the MW/EM source 950 is a microwave source, and the modulated MW/EM field 952 is a modulated microwave field.

In some embodiments, at least a portion of the plurality of color centers 930 are located in the voids 920. In some embodiments, the plurality of color centers 930 correspond to the plurality of color centers 510 (FIG. 5) and/or to the plurality of color centers 610 (FIG. 6). While the color centers 930 in FIG. 9 are illustrated as being located in or on the silicon carbide core 910, the color centers 930 do not need to include color centers located in or on the silicon carbide core 910; in some embodiments, the color centers 930 are just located in the voids 920.

In some embodiments, the silicon carbide core 910 corresponds to the core 310 and the voids 920 correspond to the voids 320 (FIG. 3, already discussed). In some embodiments, the silicon carbide core 910 has an optional cladding layer (e.g., as illustrated in FIG. 9), such as the cladding layer 410 (FIGS. 4A-4B, already discussed), and the voids 920 correspond to the voids 420 (FIGS. 4A-4B, already discussed). For illustrative purposes, in FIG. 9, the optional cladding layer is shown such that the core 910 appears partially visible (e.g., as if a portion of the cladding layer has been removed).

A power supply (not shown in FIG. 9) is used to supply power to the light source 940, the MW/EM source 950, and the imaging sensor array 960. The light source 940 is placed adjacent to a first side (e.g., edge) of the quantum sensor 905 and acts as an activation light pump to provide light rays 942 to the quantum sensor 905. In some embodiments the light source 940 includes a laser. In some embodiments the light source 940 includes a light emitting diode (LED) array. In some embodiments the light source 940 includes an array of photoluminescent quantum dots. A quantum dot is a complex stack of active material (e.g., nanocrystals of a semiconducting material) that emits light when power (such as, e.g., a DC voltage) is applied to the quantum dot. When energized (e.g., switched on or powered on), the light source 940 produces a series of light rays 942 at a first frequency. At least some of the light rays 942 enter the quantum sensor 905 and expose (e.g., irradiate or illuminate) one or more of the color centers 930 to light at the first frequency. For example, as illustrated in FIG. 9 light rays 942 enter the silicon carbide core 910 and expose respective color centers 930 to light at the first frequency. When exposed to light rays 942 at the first frequency, the respective color centers 930 emit light-- e.g., light rays 944-- at a second frequency. The emitted light rays (e.g., the light rays 944) propagate through the quantum sensor until exiting and reaching the imaging sensor array 960. In embodiments where the color centers 930 are located in or on the silicon carbide core 910 and the silicon carbide core 910 has a cladding layer with different refractive index (e.g., as described herein with reference to FIGS. 4A-4B), the cladding layer serves to guide the light rays 944 through the core 910. In embodiments, some light from the light source 940 also propagates through the quantum sensor 905.

The imaging sensor array 960 corresponds to the light detector 150 (FIG. 1, already discussed) and includes a plurality of individual pixels 962 (e.g., sensor elements). For example, in embodiments the pixels 962 are CMOS pixels (i.e., the imaging sensor array 960 is a CMOS imaging array). In embodiments the pixels 962 are arranged on a substrate 964 (e.g., to hold the pixels 962 in place). The imaging sensor array 960 is placed adjacent to a second side (e.g., edge) of the quantum sensor 905, to detect light emitted from the quantum sensor 905 (which can include light rays 944 emitted by the color centers 930 as well as some light rays 942 from the light source 940). For example, detecting or measuring light output of the quantum sensor 905 includes reading out pixels 962 from the imaging sensor array 960. Use of an array of sensors 962 enables the quantum sensing apparatus 900 to spatially measure the response of the color centers 930 in the quantum sensor 905 to the input light from the light source 940 and any external stimulus. Thus, use of the quantum sensing apparatus 900 enables determination of the strength and direction of an external stimulus based on the response of the color centers 930.

For example, the strength and direction of an external stimulus can be determined with a spatial resolution on the order of the spacing of pixels 962 and/or the spacing of the 3D lattice structure of the quantum sensor 905. In embodiments, the 3D lattice structure of the quantum sensor 905 can be formed with any structural arrangement where it is desirable to monitor physical attributes (external stimuli). For example, the lattice spacing of the 3D lattice structure can be tuned to select for certain wavelengths of light at different lattice depths, and Bayesian analysis can be applied to the output of the quantum sensing apparatus 900 to determine the gradient of the measured field, e.g., along the depth of the quantum sensing apparatus 900 (e.g., in the direction between the light source 940 and the imaging sensor array 960). In some embodiments, the depth of the quantum sensor 905 (e.g., the direction between the light source 940 and the imaging sensor array 960) is limited relative to dimensionality of the quantum sensor 905 in other directions (e.g., directions perpendicular to the depth).

In some embodiments the second side (for placement of the imaging sensor array 960) is on an opposite side of the quantum sensor 905 relative to the first side (for placement of the light source 940), for example as illustrated in FIG. 9. In some other embodiments, the second side is adjacent to the first side (e.g., the second side is at a 90 degree angle relative to the first side). While in FIG. 9 the imaging sensor array 960 is illustrated as one-dimensional (since the quantum sensor is illustrated as a 2D slice), it will be understood that in typical applications the imaging sensor array will be a two-dimensional array of pixels 962.

In embodiments, the imaging sensor array 960 is aligned such that each pixel of the imaging sensor array is to receive light emitted from a respective portion of the quantum sensor 905. In some embodiments, the lattice spacing of the quantum sensor 905 (i.e., a spacing of the 3D lattice structure of the quantum sensor 905) is the same (or approximately the same) as the pixel spacing of the imaging sensor array 960 (e.g., as illustrated in FIG. 9). That is, in some embodiments the pitch of the 3D lattice structure of the quantum sensor 905 matches (at least approximately) the pitch of the pixels 962 in the imaging sensor array 960. For example, in some embodiments where the color centers 930 are located in or on the core 910 of the quantum sensor 905, the imaging sensor array 960 is aligned such that the pixels 962 line up (at least approximately) with portions of the core 910. As another example, in some embodiments where the color centers 930 are located in the voids 920 of the quantum sensor 905, the imaging sensor array 960 is aligned such that the pixels 962 line up (at least approximately) with the voids 920. In some embodiments, the pixel spacing of the imaging sensor array 960 has a finer spacing than the lattice spacing of the quantum sensor 905.

In some embodiments, the quantum sensing apparatus 900 further includes a filter layer 970 arranged between the quantum sensor 905 and the imaging sensor array 960. In some embodiments, the filter layer 970 includes a filter material selected to permit light of the second frequency (e.g., light emitted by the color centers 930) to pass through the filter layer and to block light of the first frequency (e.g., light from the light source 940). By blocking light of the first frequency from the light source 940, the filter layer 970 enables the pixels 962 of the imaging sensor array 960 to more accurately detect/measure the light of the second frequency emitted by the color centers 930. As one example, if the color centers 930 emit red light and the light source 940 emits green light, the filter material is selected (e.g., a red filter) to permit the red light from the color centers 930 to pass through and to block the green light from the light source 940. As another example, if the color centers 930 emit green light and the light source 940 emits red light, the filter material is selected (e.g., a green filter) to permit the green light from the color centers 930 to pass through and to block the red light from the light source 940.

In some embodiments, the filter layer 970 includes a plurality of filter elements aligned with a plurality of pixels 962 in the imaging sensor array 960, such as filter elements 972. In some embodiments each of the filter elements 972 (e.g., which can be a subset of the plurality of filter elements) includes a first filter material selected to permit light of the second frequency (e.g., light emitted by the color centers 930) to pass through the filter layer and block light of the first frequency (e.g., light from the light source 940).

In some embodiments the plurality of filter elements also include one or more reference filter element(s) 974. For example, in some embodiments a reference filter element 974 is repeated periodically in the filter layer 970. Each of the one or more reference filter element(s) 974 includes a second filter material selected to permit light of the first frequency (e.g., light from the light source 940) to pass through the filter layer and block light of the second frequency (e.g., light emitted by the color centers 930).

By using a filter layer with two types of filter elements, the imaging sensor apparatus 900 enables measurement of light from the light source 940 passing through the quantum sensor 905 (e.g., via pixel(s) adjacent to the one or more reference filter element(s) 974) as well as measurement of light emitted by the color centers 930 (e.g., via pixels adjacent to the filter elements 972). Having measurement of light from the light source 940 passing through the quantum sensor 905 and measurement of light emitted by the color centers 930 enables, in turn, calibration of the output of the quantum sensing apparatus 900. For example, calibrating the output of the quantum sensing apparatus 900 is performed based on comparing an output of at least one pixel 962 adjacent to a filter element 972 (e.g., having the first filter material) to an output of at least one pixel 962 adjacent to a reference filter element 974 (e.g., having the second filter material).

Calibration can be further based on using known directionality of various stimuli inputs. As one example, for crystalline substrates, it can be deduced in which direction the crystalline defect lies, and thus the vector of the spin-defect. By arranging three pieces of quantum material such that all spin-defects are orthogonal to each other, then the vector field of a test stimulus can be determined (e.g., in the case of magnetic or electric field stimuli).

FIG. 10 provides a process flow diagram illustrating an example method 1000 of operating a quantum sensing apparatus according to one or more embodiments, with reference to components and features described herein including but not limited to the figures and associated description. All or part of the method 1000 can be implemented as one or more modules as a set of program or logic instructions stored in a machine-or computer-readable storage medium such as random access memory (RAM), read only memory (ROM), programmable ROM (PROM), firmware, flash memory, etc., in hardware, or any combination thereof. For example, hardware implementations can include configurable logic, fixed-functionality logic, or any combination thereof. Examples of configurable logic include suitably configured programmable logic arrays (PLAs), FPGAs, complex programmable logic devices (CPLDs), and general purpose microprocessors. Examples of fixed-functionality logic include suitably configured ASICs, combinational logic circuits, and sequential logic circuits. The configurable or fixed-functionality logic can be implemented with complementary metal oxide semiconductor (CMOS) logic circuits, transistor-transistor logic (TTL) logic circuits, or other circuits.

For example, computer program code to carry out operations shown in the method 1000 and/or functions associated therewith can be written in any combination of one or more programming languages, including an object-oriented programming language such as Java, JavaScript, Python, C #, C++, Perl, Smalltalk, or the like and conventional procedural programming languages, such as the “C” programming language or similar programming languages. Additionally, program or logic instructions might include assembler instructions, instruction set architecture (ISA) instructions, machine instructions, machine dependent instructions, microcode, state-setting data, configuration data for integrated circuitry, state information that personalizes electronic circuitry and/or other structural components that are native to hardware (e.g., host processor, central processing unit/CPU, microcontroller, etc.).

Illustrated process block 1010 provides for supplying power to a quantum sensing apparatus. The quantum sensing apparatus includes a quantum sensor, a light source to emit light at a first frequency, where the light source is arranged adjacent to a first side of the quantum sensor, an imaging sensor array arranged adjacent to a second side of the quantum sensor, and an electromagnetic field source adjacent to the quantum sensor, wherein the electromagnetic field source is to emit a modulated electromagnetic field into the quantum sensor. The quantum sensor includes a three-dimensional (3D) lattice structure, the three-dimensional (3D) lattice structure including a silicon carbide core and a plurality of voids, and a plurality of color centers located within a boundary of the 3D lattice structure, where each of the plurality of color centers comprises a single-defect photon emitter. When exposed to light at the first frequency, each of the plurality of color centers (i.e., the color centers so exposed) emits light at a second frequency. For respective ones of the plurality of color centers, an intensity of the light emitted at the second frequency varies based on exposure of the respective ones of the plurality of color centers to an external stimulus. In embodiments the quantum sensing apparatus corresponds to the quantum sensing apparatus 900 (FIG. 9, already discussed).

Illustrated process block 1020 provides for exposing the quantum sensing apparatus to an external stimulus. In embodiments the external stimulus includes one or more of a magnetic field, an electric field, a thermal field, or a strain field imparted to the 3D lattice structure.

Illustrated process block 1030 provides for measuring an output of the quantum sensing apparatus after the power is supplied to the quantum sensing apparatus. For example, measuring an output of the quantum sensor includes reading out pixels of the imaging sensor array of the quantum sensing apparatus. In some embodiments, the quantum sensing apparatus includes a filter layer arranged between the quantum sensor and the imaging sensor array, where the filter layer includes a filter material selected to permit light of the second frequency to pass through the filter layer and to block light of the first frequency.

In some embodiments, the quantum sensing apparatus includes a filter layer arranged between the quantum sensor and the imaging sensor array, where the filter layer includes a plurality of filter elements aligned with a plurality of pixels in the imaging sensor array, where a subset of the plurality of filter elements each includes a first filter material selected to permit light of the second frequency to pass through the filter layer and block light of the first frequency, and where at least one filter element (e.g., a reference filter element) of the plurality of filter elements includes a second filter material selected to permit light of the first frequency to pass through the filter layer and block light of the second frequency. In some embodiments, the method 1000 further includes calibrating the output of the quantum sensing apparatus based on comparing an output of at least one pixel adjacent to a filter element having the first filter material to an output of at least one pixel adjacent to a filter element (e.g., a reference filter element) having the second filter material.

Illustrated process block 1040 provides for determining from the output of the quantum sensing apparatus a strength and direction of the external stimulus. For example, given prior device calibration using known directionality of various stimuli inputs in combination with the known lattice structure of the quantum sensor, the strength and direction of an arbitrary external stimulus is determined based on the output of the pixels of the imaging sensor array. In embodiments, the modulated electromagnetic field is a modulated microwave field. In embodiments, determining the strength and direction of the external stimulus includes using an Optically Detected Magnetic Resonance (ODMR) technique.

### Additional Notes and Examples

Example S1 includes a quantum sensor comprising a three-dimensional (3D) lattice structure comprising a silicon carbide core and a plurality of voids, and a plurality of color centers located within a boundary of the 3D lattice structure, wherein each of the plurality of color centers comprises a single-defect photon emitter.

Example S2 includes the quantum sensor of Example S1, wherein at least a portion of the plurality of color centers are located in or on the silicon carbide core of the 3D lattice structure.

Example S3 includes the quantum sensor of Example S1 or S2, wherein one or more of the plurality of color centers comprises silicon carbide.

Example S4 includes the quantum sensor of any of Examples S1-S3, wherein at least a portion of the plurality of color centers are located in one or more of the voids of the 3D lattice structure.

Example S5 includes the quantum sensor of any of Examples S1-S4, wherein one or more of the plurality of color centers comprises a nitrogen vacancy defective diamond material.

Example S6 includes the quantum sensor of any of Examples S1-S5, wherein the 3D lattice structure further comprises a cladding layer disposed over at least a portion of the silicon carbide core, and wherein the cladding layer comprises a first material having a first refractive index that is different than a refractive index of the silicon carbide core.

Example S7 includes the quantum sensor of Example S6, wherein the first refractive index is lower than the refractive index of the silicon carbide core.

Example S8 includes the quantum sensor of Example S6 or S7, wherein the first material of the cladding layer comprises aluminum oxide or silicon dioxide.

Example S9 includes the quantum sensor of any of Examples S1-S8, wherein, when exposed to light at a first frequency, each of the plurality of color centers is to emit light at a second frequency, and wherein, for a respective one of the plurality of color centers, an intensity of the light to be emitted at the second frequency is to vary based on exposure of the respective one of the plurality of color centers to an external stimulus.

Example S10 includes the quantum sensor of Example S9, wherein the external stimulus comprises one or more of a magnetic field, an electric field, an electromagnetic field, a thermal field, or a strain field imparted to the 3D lattice structure.

Example M1 includes a method comprising forming a porous mask in a substrate via interference lithography, wherein the porous mask defines a three-dimensional grid pattern, introducing silicon carbide into the porous mask, wherein the silicon carbide is in the form of silicon carbide powder or a silicon carbide slurry, sintering or curing the silicon carbide at a first temperature to form a green body ceramic part, and after removal of the porous mask, sintering the green body ceramic part at a second temperature to form a three-dimensional (3D) lattice structure, wherein the second temperature is higher than the first temperature, and wherein the 3D lattice structure comprises a silicon carbide core and a plurality of voids.

Example M2 includes the method of Example M1, wherein the silicon carbide includes a plurality of color centers, wherein each of the plurality of color centers comprises a single-defect photon emitter, and wherein when the 3D lattice structure is formed the plurality of color centers are located within a boundary of the 3D lattice structure.

Example M3 includes the method of Example M1 or M2, wherein the silicon carbide slurry includes liquid sodium water glass.

Example M4 includes the method of Example M3, wherein the silicon carbide slurry further includes zirconium dioxide.

Example M5 includes the method of any of Examples M1-M4, further comprising introducing a plurality of color centers into one or more of the voids of the 3D lattice structure.

Example M6 includes the method of any of Examples M1-M5, further comprising laser writing a plurality of color centers in or on the silicon carbide core of the 3D lattice structure.

Example M7 includes the method of any of Examples M1-M6, further comprising disposing a cladding layer over at least a portion of the silicon carbide core of the 3D lattice structure, wherein the cladding layer comprises a first material having a first refractive index that is different than a refractive index of the silicon carbide core.

Example M8 includes the method of Example M7, wherein disposing the cladding layer over at least the portion of the silicon carbide core of the 3D lattice structure comprises immersing the 3D lattice structure into a mixture comprising aluminum oxide or silicon dioxide to form an uncured layer, partially curing the uncured layer via laser exposure to form a partially cured layer, removing any remaining uncured portion of the uncured layer, and sintering the partially cured layer.

Example A1 includes an apparatus comprising a quantum sensor comprising a three-dimensional (3D) lattice structure comprising a silicon carbide core and a plurality of voids, and a plurality of color centers located within a boundary of the 3D lattice structure, wherein each of the plurality of color centers comprises a single-defect photon emitter, a light source to emit light at a first frequency, wherein the light source is arranged adjacent to a first side of the quantum sensor and is to emit the light at the first frequency into the quantum sensor, an imaging sensor array arranged adjacent to a second side of the quantum sensor, and an electromagnetic field source adjacent to the quantum sensor, wherein the electromagnetic field source is to emit a modulated electromagnetic field into the quantum sensor.

Example A2 includes the apparatus of Example A1, wherein a spacing of the 3D lattice structure is sized to match a spacing of pixels of the imaging sensor array, and wherein the imaging sensor array is aligned such that each pixel of the imaging sensor array is to receive light emitted from a respective portion of the quantum sensor.

Example A3 includes the apparatus of Example A1 or A2, wherein the second side of the quantum sensor is on an opposite side relative to the first side of the quantum sensor.

Example A4 includes the apparatus of any of Examples A1-A3, wherein, when exposed to light at the first frequency, each of the plurality of color centers is to emit light at a second frequency, and wherein, for respective ones of the plurality of color centers, an intensity of the light to be emitted at the second frequency is to vary based on exposure of the respective ones of the plurality of color centers to an external stimulus.

Example A5 includes the apparatus of Example A4, wherein the external stimulus comprises one or more of a magnetic field, an electric field, an electromagnetic field, a thermal field, or a strain field imparted to the 3D lattice structure.

Example A6 includes the apparatus of Example A4 or A5, further comprising a filter layer arranged between the quantum sensor and the imaging sensor array.

Example A7 includes the apparatus of Example A6, wherein the filter layer comprises a filter material selected to permit light of the second frequency to pass through the filter layer and to block light of the first frequency.

Example A8 includes the apparatus of Example A6, wherein the filter layer comprises a plurality of filter elements aligned with a plurality of pixels in the imaging sensor array, wherein a subset of the plurality of filter elements each comprises a first filter material selected to permit light of the second frequency to pass through the filter layer and block light of the first frequency, and wherein at least one filter element of the plurality of filter elements comprises a second filter material selected to permit light of the first frequency to pass through the filter layer and block light of the second frequency.

Example A9 includes the apparatus of any of Examples A1-A8, wherein the modulated electromagnetic field is a modulated microwave field.

Example MA1 includes a method comprising supplying power to a quantum sensing apparatus, exposing the quantum sensing apparatus to an external stimulus, measuring an output of the quantum sensing apparatus after the power is supplied to the quantum sensing apparatus, and determining from the output of the quantum sensing apparatus a strength and direction of the external stimulus, wherein the quantum sensing apparatus comprises a quantum sensor comprising a three-dimensional (3D) lattice structure comprising a silicon carbide core and a plurality of voids, and a plurality of color centers located within a boundary of the 3D lattice structure, wherein each of the plurality of color centers comprises a single-defect photon emitter, a light source to emit light at a first frequency, wherein the light source is arranged adjacent to a first side of the quantum sensor and is to emit the light at the first frequency into the quantum sensor, an imaging sensor array arranged adjacent to a second side of the quantum sensor, and an electromagnetic field source adjacent to the quantum sensor, wherein the electromagnetic field source is to emit a modulated electromagnetic field into the quantum sensor, wherein, when exposed to light at the first frequency and to the modulated electromagnetic field, each of the plurality of color centers emits light at a second frequency, and wherein, for respective ones of the plurality of color centers, an intensity of the light emitted at the second frequency varies based on exposure of the respective ones of the plurality of color centers to an external stimulus.

Example MA2 includes the method of Example MA1, wherein measuring an output of the quantum sensor comprises reading out pixels of the imaging sensor array.

Example MA3 includes the method of Example MA1 or MA2, wherein the quantum sensing apparatus further comprises a filter layer arranged between the quantum sensor and the imaging sensor array, and wherein the filter layer comprises a filter material selected to permit light of the second frequency to pass through the filter layer and to block light of the first frequency.

Example MA4 includes the method of any of Examples MA1-MA3, wherein the quantum sensing apparatus further comprises a filter layer arranged between the quantum sensor and the imaging sensor array, wherein the filter layer comprises a plurality of filter elements aligned with a plurality of pixels in the imaging sensor array, wherein a subset of the plurality of filter elements each comprises a first filter material selected to permit light of the second frequency to pass through the filter layer and block light of the first frequency, and wherein at least one filter element of the plurality of filter elements comprises a second filter material selected to permit light of the first frequency to pass through the filter layer and block light of the second frequency.

Example MA5 includes the method of Example MA4, further comprising calibrating the output of the quantum sensing apparatus based on comparing an output of at least one pixel adjacent to a filter element having the first filter material to an output of at least one pixel adjacent to a filter element having the second filter material.

Example MA6 includes the method of any of Examples MA1-MA5, wherein the external stimulus comprises one or more of a magnetic field, an electric field, a thermal field, or a strain field imparted to the 3D lattice structure.

Example MA7 includes the method of any of Examples MA1-MA6, wherein the modulated electromagnetic field is a modulated microwave field.

Example QA1 includes an apparatus comprising means for performing the method of any of Examples MA1 to MA7.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), solid state drive (SSD)/NAND drive controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the platform within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections, including logical connections via intermediate components (e.g., device A may be coupled to device C via device B). In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A quantum sensor comprising:
a three-dimensional (3D) lattice structure comprising a silicon carbide core and a plurality of voids; and
a plurality of color centers located within a boundary of the 3D lattice structure, wherein each of the plurality of color centers comprises a single-defect photon emitter.

2. The quantum sensor of claim 1, wherein at least a portion of the plurality of color centers are located in or on the silicon carbide core of the 3D lattice structure.

3. The quantum sensor of claim 2, wherein one or more of the plurality of color centers comprises silicon carbide.

4. The quantum sensor of claim 1, wherein at least a portion of the plurality of color centers are located in one or more of the voids of the 3D lattice structure.

5. The quantum sensor of claim 4, wherein one or more of the plurality of color centers comprises a nitrogen vacancy defective diamond material.

6. The quantum sensor of claim 1, wherein the 3D lattice structure further comprises a cladding layer disposed over at least a portion of the silicon carbide core, and
wherein the cladding layer comprises a first material having a first refractive index that is different than a refractive index of the silicon carbide core.

7. The quantum sensor of claim 6, wherein the first refractive index is lower than the refractive index of the silicon carbide core.

8. The quantum sensor of claim 7, wherein the first material of the cladding layer comprises aluminum oxide or silicon dioxide.

9. The quantum sensor of claim 1, wherein, when exposed to light at a first frequency, each of the plurality of color centers is to emit light at a second frequency; and
wherein, for a respective one of the plurality of color centers, an intensity of the light to be emitted at the second frequency is to vary based on exposure of the respective one of the plurality of color centers to an external stimulus.

10. The quantum sensor of claim 9, wherein the external stimulus comprises one or more of a magnetic field, an electric field, an electromagnetic field, a thermal field, or a strain field imparted to the 3D lattice structure.

11. A method comprising:
forming a porous mask in a substrate via interference lithography, wherein the porous mask defines a three-dimensional grid pattern;
introducing silicon carbide into the porous mask, wherein the silicon carbide is in the form of silicon carbide powder or a silicon carbide slurry;
sintering or curing the silicon carbide at a first temperature to form a green body ceramic part; and
after removal of the porous mask, sintering the green body ceramic part at a second temperature to form a three-dimensional (3D) lattice structure,
wherein the second temperature is higher than the first temperature, and wherein the 3D lattice structure comprises a silicon carbide core and a plurality of voids.

12. The method of claim 11, wherein the silicon carbide includes a plurality of color centers, wherein each of the plurality of color centers comprises a single-defect photon emitter, and
wherein when the 3D lattice structure is formed the plurality of color centers are located within a boundary of the 3D lattice structure.

13. The method of claim 11, wherein the silicon carbide slurry includes liquid sodium water glass.

14. The method of claim 13, wherein the silicon carbide slurry further includes zirconium dioxide.

15. The method of claim 11, further comprising introducing a plurality of color centers into one or more of the voids of the 3D lattice structure.

16. The method of claim 11, further comprising laser writing a plurality of color centers in or on the silicon carbide core of the 3D lattice structure.

17. The method of claim 11, further comprising disposing a cladding layer over at least a portion of the silicon carbide core of the 3D lattice structure,
wherein the cladding layer comprises a first material having a first refractive index that is different than a refractive index of the silicon carbide core.

18. The method of claim 17, wherein disposing the cladding layer over at least the portion of the silicon carbide core of the 3D lattice structure comprises:
immersing the 3D lattice structure into a mixture comprising aluminum oxide or silicon dioxide to form an uncured layer;
partially curing the uncured layer via laser exposure to form a partially cured layer;
removing any remaining uncured portion of the uncured layer; and
sintering the partially cured layer.

19. An apparatus comprising:
a quantum sensor comprising:
a three-dimensional (3D) lattice structure comprising a silicon carbide core and a plurality of voids; and
a plurality of color centers located within a boundary of the 3D lattice structure, wherein each of the plurality of color centers comprises a single-defect photon emitter;
a light source to emit light at a first frequency, wherein the light source is arranged adjacent to a first side of the quantum sensor and is to emit the light at the first frequency into the quantum sensor;
an imaging sensor array arranged adjacent to a second side of the quantum sensor; and
an electromagnetic field source adjacent to the quantum sensor, wherein the electromagnetic field source is to emit a modulated electromagnetic field into the quantum sensor.

20. The apparatus of claim 19, wherein a spacing of the 3D lattice structure is sized to match a spacing of pixels of the imaging sensor array, and wherein the imaging sensor array is aligned such that each pixel of the imaging sensor array is to receive light emitted from a respective portion of the quantum sensor.

21. The apparatus of claim 19, wherein the second side of the quantum sensor is on an opposite side relative to the first side of the quantum sensor.

22. The apparatus of claim 19, wherein, when exposed to light at the first frequency, each of the plurality of color centers is to emit light at a second frequency; and
wherein, for respective ones of the plurality of color centers, an intensity of the light to be emitted at the second frequency is to vary based on exposure of the respective ones of the plurality of color centers to an external stimulus.

23. The apparatus of claim 22, wherein the external stimulus comprises one or more of a magnetic field, an electric field, an electromagnetic field, a thermal field, or a strain field imparted to the 3D lattice structure.

24. The apparatus of claim 22, further comprising a filter layer arranged between the quantum sensor and the imaging sensor array.

25. The apparatus of claim 24, wherein the filter layer comprises a filter material selected to permit light of the second frequency to pass through the filter layer and to block light of the first frequency.

26. The apparatus of claim 24, wherein the filter layer comprises a plurality of filter elements aligned with a plurality of pixels in the imaging sensor array,
wherein a subset of the plurality of filter elements each comprises a first filter material selected to permit light of the second frequency to pass through the filter layer and block light of the first frequency, and
wherein at least one filter element of the plurality of filter elements comprises a second filter material selected to permit light of the first frequency to pass through the filter layer and block light of the second frequency.

27. The apparatus of claim 19, wherein the modulated electromagnetic field is a modulated microwave field.

28. A method comprising:
supplying power to a quantum sensing apparatus;
exposing the quantum sensing apparatus to an external stimulus;
measuring an output of the quantum sensing apparatus after the power is supplied to the quantum sensing apparatus; and
determining from the output of the quantum sensing apparatus a strength and direction of the external stimulus;
wherein the quantum sensing apparatus comprises:
a quantum sensor comprising:
a three-dimensional (3D) lattice structure comprising a silicon carbide core and a plurality of voids; and
a plurality of color centers located within a boundary of the 3D lattice structure, wherein each of the plurality of color centers comprises a single-defect photon emitter;
a light source to emit light at a first frequency, wherein the light source is arranged adjacent to a first side of the quantum sensor and is to emit the light at the first frequency into the quantum sensor;
an imaging sensor array arranged adjacent to a second side of the quantum sensor; and
an electromagnetic field source adjacent to the quantum sensor, wherein the electromagnetic field source is to emit a modulated electromagnetic field into the quantum sensor;
wherein, when exposed to light at the first frequency and to the modulated electromagnetic field, each of the plurality of color centers emits light at a second frequency; and
wherein, for respective ones of the plurality of color centers, an intensity of the light emitted at the second frequency varies based on exposure of the respective ones of the plurality of color centers to an external stimulus.

29. The method of claim 28, wherein measuring an output of the quantum sensor comprises reading out pixels of the imaging sensor array.

30. The method of claim 28, wherein the quantum sensing apparatus further comprises a filter layer arranged between the quantum sensor and the imaging sensor array, and
wherein the filter layer comprises a filter material selected to permit light of the second frequency to pass through the filter layer and to block light of the first frequency.

31. The method of claim 28, wherein the quantum sensing apparatus further comprises a filter layer arranged between the quantum sensor and the imaging sensor array,
wherein the filter layer comprises a plurality of filter elements aligned with a plurality of pixels in the imaging sensor array,
wherein a subset of the plurality of filter elements each comprises a first filter material selected to permit light of the second frequency to pass through the filter layer and block light of the first frequency, and
wherein at least one filter element of the plurality of filter elements comprises a second filter material selected to permit light of the first frequency to pass through the filter layer and block light of the second frequency.

32. The method of claim 31, further comprising calibrating the output of the quantum sensing apparatus based on comparing an output of at least one pixel adjacent to a filter element having the first filter material to an output of at least one pixel adjacent to a filter element having the second filter material.

33. The method of claim 28, wherein the external stimulus comprises one or more of a magnetic field, an electric field, a thermal field, or a strain field imparted to the 3D lattice structure.

34. The method of claim 28, wherein the modulated electromagnetic field is a modulated microwave field.
